(19) United States
(12) Patent Application Publication
(10) Pub. No.: US 2025/0167087 A1
(43) Pub. Date: May 22, 2025

(54) SEMICONDUCTOR PACKAGE WITH SUBSTRATE PAD

(71) Applicant: SAMSUNG ELECTRONICS CO., LTD., Suwon-si (KR)

(72) Inventors: Dowan Kim, Suwon-si (KR); Seung Hun Chae, Suwon-si (KR); Un-Byoung Kang, Suwon-si (KR)

(21) Appl. No.: 18/775,998

(22) Filed: Jul. 17, 2024

(30) Foreign Application Priority Data
Nov. 16, 2023 (KR) 10-2023-0159526
Dec. 27, 2023 (KR) 10-2023-0192077

(51) Int. Cl. H01L 23/498; H01L 21/48; H01L 21/768; H01L 23/00

(52) U.S. Cl. CPC H01L 23/49822; H01L 21/4857; H01L 21/76879; H01L 23/49833; H01L 23/49838; H01L 23/49866; H01L 23/562; H01L 24/05; H01L 24/16; H01L 2224/05082; H01L 2224/05155; H01L 2224/05639; H01L 2224/05644; H01L 2224/16237; H01L 2924/1815

(57) ABSTRACT

A semiconductor package includes a wiring substrate that includes a wiring pattern, a dielectric pattern that covers the wiring pattern, a substrate pad on the dielectric pattern and including a recess that extends from a top surface of the substrate pad toward an inside of the substrate pad, a metal layer on a bottom surface of the recess and spaced apart from an inner lateral surface of the recess, and a protection layer on the dielectric pattern and covering the substrate pad. The substrate pad penetrates the dielectric pattern to come into connection with the wiring pattern. The protection layer exposes at least a portion of the metal layer. The protection layer extends from the top surface of the substrate pad to fill a space between a lateral surface of the metal layer and the inner lateral surface of the recess.

### CROSS-REFERENCE TO RELATED APPLICATIONS

This U.S. nonprovisional application claims priority under 35 U.S.C § 119 to Korean Patent Applications No. 10-2023-0159526, filed on Nov. 16, 2023, and No. 10-2023-0192077, filed on Dec. 27, 2023, in the Korean Intellectual Property Office, the disclosures of which are hereby incorporated by reference in their entirety.

### BACKGROUND

With the development of electronic industry, electronic products have increasing demands for high performance, high speed, and compact size. Therefore, a substrate on which a semiconductor chip is mounted also benefits from fine circuitry, excellent electrical properties, high reliability, high-speed signal transfer structure, and high functionality.

A solder resist may be included on a surface of the semiconductor package substrate. The solder resist is generally stacked on a surface of a wiring substrate when soldering is typically employed to couple with electrodes and leads on the wiring substrate.

### SUMMARY

Some aspects of the present disclosure provide a semiconductor package with improved structural stability, and a methods of fabricating the same. For example, to provide superior electrical properties of semiconductor packages, some implementations described herein provide techniques for stably stacking solder resist on a wiring substrate and maintaining the packaging under various environment.

The objects and advantages provided herein are not limited to those mentioned above, and other objects and advantages which have not been mentioned above will be clearly understood to those skilled in the art from the following description.

According to some implementations, a wiring substrate may include: a wiring pattern; a dielectric pattern that covers the wiring pattern; a substrate pad on the dielectric pattern, the substrate pad including a recess that extends from a top surface of the substrate pad toward an inside of the substrate pad; a metal layer on a bottom surface of the recess and spaced apart from an inner lateral surface of the recess; and a protection layer on the dielectric pattern, the protection layer covering the substrate pad. The substrate pad may penetrate the dielectric pattern to come into connection with the wiring pattern. The protection layer may expose at least a portion of the metal layer. The protection layer may extend from the top surface of the substrate pad to fill a space between a lateral surface of the metal layer and the inner lateral surface of the recess.

According to some implementations, a semiconductor package may include: a lower redistribution substrate; a semiconductor chip on the lower redistribution substrate; a molding layer on the lower redistribution substrate, the molding layer surrounding the semiconductor chip; an upper redistribution substrate on the molding layer; and a connection member through which the lower redistribution substrate and the upper redistribution substrate are connected on one side of the semiconductor chip. The upper redistribution substrate may include: a wiring pattern; a dielectric pattern that covers the wiring pattern; a substrate pad on the dielectric pattern, the substrate pad including a recess on a central portion of the substrate pad, the recess extending from a top surface of the substrate pad toward an inside of the substrate pad; a first metal layer on a bottom surface of the recess; a protection layer that covers the dielectric pattern; and a connection terminal on the first metal layer and a top surface of the first metal layer. The first metal layer may include: a lower metal layer; and an upper metal layer that protrudes onto a central portion of a top surface of the lower metal layer. A width of the lower metal layer may be greater than a width of the upper metal layer. The lower metal layer may cover the bottom surface of the recess.

According to some implementations, a method of fabricating a semiconductor package may include: forming a wiring pattern and a dielectric pattern that covers the wiring pattern; forming on the dielectric pattern a substrate pad that penetrates the dielectric pattern to come into connection with the wiring pattern; forming a first sacrificial layer on the dielectric pattern; allowing the first sacrificial layer to undergo an exposure process to form a first opening that exposes a central portion of the substrate pad; using the first sacrificial layer as an etching mask to etch the substrate pad to form a recess in the substrate pad; removing the first sacrificial layer; forming a second sacrificial layer on the dielectric pattern; allowing the second sacrificial layer to undergo an exposure process to form a second opening that exposes a central portion of the recess, the second opening being spaced apart from an inner lateral surface of the recess; forming a metal layer on the central portion of the recess, the central portion of the recess being exposed by the second opening; removing the second sacrificial layer; forming on the dielectric pattern a substrate protection layer that covers the substrate pad; allowing the substrate protection layer to undergo a laser process to form a third opening that exposes a top surface of the metal layer; and forming a connection terminal on the exposed top surface of the metal layer.

### BRIEF DESCRIPTION OF DRAWINGS

FIG. 1 is a cross-sectional view showing a semiconductor package according to some implementations.

FIG. 2 is an enlarged view of section A depicted in FIG. 1 some implementations.

FIGS. 3 to 5 are cross-sectional views of second upper pads according to some implementations.

FIGS. 6 and 7 are cross-sectional views showing a semiconductor package according to some implementations.

FIG. 8 is an enlarged view of section C depicted in FIG. 7, some implementations.

FIG. 9 is a cross-sectional view showing a semiconductor package according to some implementations.

FIGS. 10 to 13 are cross-sectional views showing a method of fabricating a semiconductor package according to some implementations.

### DETAILED DESCRIPTION

The following will now describe various examples according to the present disclosure, with reference to the accompanying drawings.

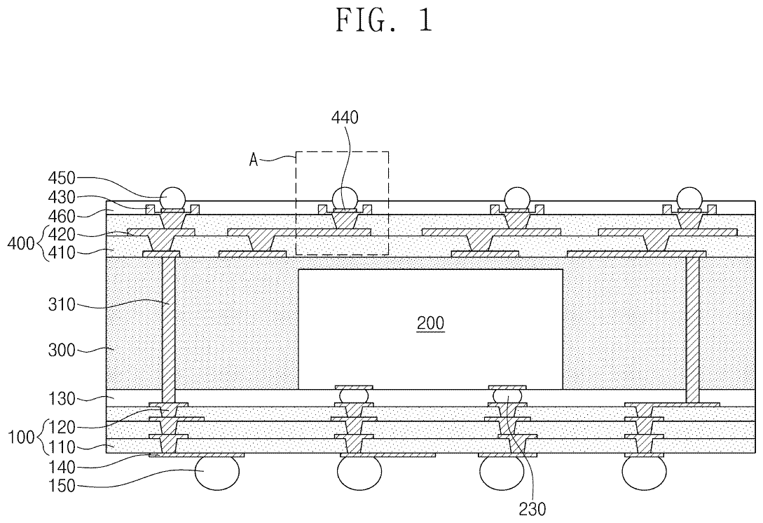

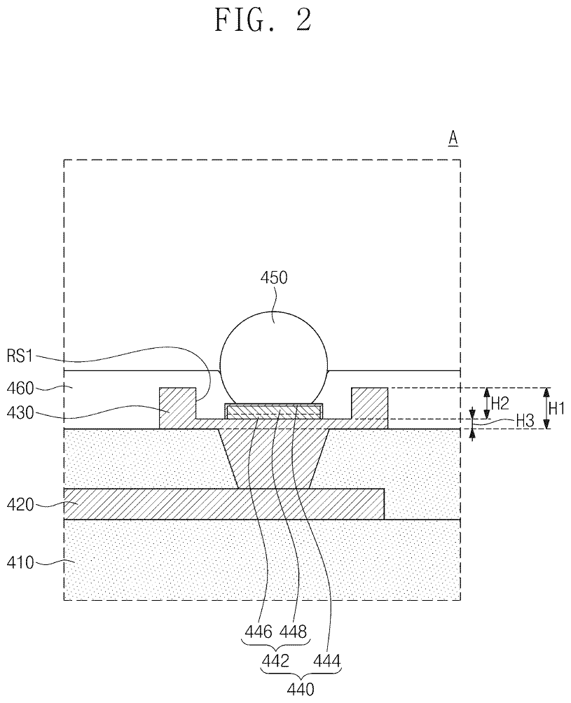

FIG. 1 illustrates a cross-sectional view showing a semiconductor package according to some implementations. For convenience of description, some components will be omitted or many of components will be merged into a single configuration in FIG. 1. FIG. 2 illustrates an enlarged view of section A depicted in FIG. 1, showing second upper pads according to some implementations.

Referring to FIG. 1, a first redistribution substrate 100 may be provided. The first redistribution substrate 100 may include a single first substrate wiring layer or at least two first substrate wiring layers that are stacked on each other. In this description, the term “first substrate wiring layer” may refer to a substrate wiring layer of the first redistribution substrate 100 formed by respectively patterning one dielectric material layer and one conductive material layer. For example, conductive patterns in one first substrate wiring layer may be wiring lines that horizontally extend and do not vertically overlap each other (e.g., are horizontally spaced apart from one another). Each of the first substrate wiring layers may include a first dielectric pattern 110 and a first conductive pattern 120 in the first dielectric pattern 110. The first conductive pattern 120 in one first substrate wiring layer may be electrically connected to the first conductive pattern 120 of a neighboring another first substrate wiring layer. The following will describe the first dielectric pattern 110 and the first conductive pattern 120 of the one first substrate wiring layer.

The first dielectric pattern 110 may include an inorganic dielectric layer, such as silicon oxide (SiOx) or silicon nitride (SiNx). In some implementations, the first dielectric patterns 110 may include a polymer. The first dielectric pattern 110 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers.

The first conductive pattern 120 may be provided on a top surface of the first dielectric pattern 110. The first conductive pattern 120 may protrude onto the top surface of the first dielectric pattern 110. The first conductive pattern 120 may horizontally extend on the top surface of the first dielectric pattern 110. The first conductive pattern 120 positioned on the top surface of the first dielectric pattern 110 may be covered with an overlying other first dielectric pattern 110. The first conductive pattern 120 may be a pad or wiring part of the first substrate wiring layer. For example, the first conductive pattern 120 may be a component for horizontal redistribution in the first redistribution substrate 100. The first conductive pattern 120 may include a conductive material. For example, the first conductive pattern 120 may include copper (Cu).

The first conductive pattern 120 may have a damascene structure, e.g., formed in a damascene process. For example, the first conductive pattern 120 may have a via that protrudes onto a bottom surface of the first conductive pattern 120. The via may be a component for connection between the first conductive patterns 120 that are vertically adjacent to each other. For example, the via may extend from the bottom surface of the first conductive pattern 120, and may penetrate the first dielectric pattern 110 to be coupled to a top surface of the first conductive pattern 120 of an underlying another first substrate wiring layer. In this configuration, an upper portion of the first conductive pattern 120 positioned on the first dielectric pattern 110 may be a head part used as a horizontal line or pad, and the via of the first conductive pattern 120 may be a tail part. The first conductive pattern 120 may have a T shape.

The first redistribution substrate 100 may be provided with external pads 140 thereunder. The external pads 140 may be a portion of the first conductive pattern 120 exposed on a bottom surface of the first dielectric pattern 110 in a lowermost first substrate wiring layer, or may be separate pads that are positioned on a bottom surface of a lowermost first dielectric pattern 110 to come into connection with the first conductive patterns 120. The external pads 140 may be coupled to the first conductive patterns 120.

External terminals 150 may be provided on bottom surfaces of the external pads 140. The external terminals 150 may include solder balls or solder bumps. Based on type and arrangement of the external terminals 150, a semiconductor package may be provided in the form of a ball grid array (BGA) type, a fine ball-grid array (FBGA) type, or a land grid array (LGA) type. The external terminals 150 may be electrically connected through the first redistribution substrate 100 to a semiconductor chip 200 which will be discussed below. A semiconductor package may be mounted through the external terminals 150 on an external apparatus.

A first substrate protection layer may be disposed on a bottom surface of the first redistribution substrate 100. The first substrate protection layer may cover a bottom surface of the lowermost first substrate wiring layer and expose the external pads 140. The first substrate protection layer may include a dielectric polymer such as an epoxy-based polymer, an Ajinomoto build-up film (ABF), an organic material, or an inorganic material.

The head parts of the first conductive patterns 120 in an uppermost one of the first substrate wiring layers may correspond to first upper pads of the first redistribution substrate 100. The first upper pads may be a portion of the first conductive pattern 120 that protrudes onto the top surface of the first dielectric pattern 110 of the first substrate wiring layer, or may be separate pads that are disposed on the top surface of the first dielectric pattern 110 to come into connection with the first conductive patterns 120.

A second substrate protection layer may be disposed on a top surface of the uppermost first substrate wiring layer. The second substrate protection layer may cover the top surface of the uppermost first substrate wiring layer and expose the first upper pads. The second substrate protection layer may include a dielectric polymer such as an epoxy-based polymer, an Ajinomoto build-up film (ABF), an organic material, or an inorganic material.

A semiconductor chip 200 may be disposed on the first redistribution substrate 100. The semiconductor chip 200 may include an integrated circuit. The integrated circuit may include a logic circuit or a memory circuit. For example, the semiconductor chip 200 may be a logic chip or a memory chip. The semiconductor chip 200, however, is not limited thereto, and the semiconductor chip 200 may include a logic chip, a memory chip, a passive element, or a semiconductor chip including various integrated elements. In some implementations, the semiconductor chip 200 may be a semiconductor substrate including no integrated circuit. For example, the semiconductor chip 200 may be a dummy chip including a bulk silicon substrate. The semiconductor chip 200 may be provided in a face-down state. The semiconductor chip 200 may have a bottom surface directed toward the first redistribution substrate 100 and a top surface opposite to the bottom surface. The bottom surface of the semiconductor chip 200 may be an active surface of the semiconductor chip 200. The top surface of the semiconductor chip 200 may be an inactive surface of the semiconductor chip 200.

The semiconductor chip 200 may include chip lower pads provided on the bottom surface of the semiconductor chip 200. The chip lower pads may be disposed on the bottom surface of the semiconductor chip 200. The chip lower pads may be exposed on the bottom surface of the semiconductor chip 200. The chip lower pads may be electrically connected to the integrated circuit of the semiconductor chip 200.

Chip connection terminals 230 may be provided on the bottom surface of the semiconductor chip 200. The chip connection terminals 230 may be provided on bottom surface of the chip lower pads. The chip connection terminals 230 may include solder balls or solder bumps. The chip connection terminals 230 may be electrically connected through the chip lower pads to the integrated circuit of the semiconductor chip 200. The semiconductor chip 200 may be mounted through the chip connection terminals 230 on the first upper pads of the first redistribution substrate 100. Between the first redistribution substrate 100 and the semiconductor chip 200, the chip connection terminals 230 may connect the first upper pads of the first redistribution substrate 100 to the chip lower pads of the semiconductor chip 200. For example, the semiconductor chip 200 may be flip-chip mounted on the first redistribution substrate 100.

FIG. 1 depicts that the semiconductor chip 200 is flip-chip mounted on the first redistribution substrate 100, but the configuration is not limited thereto. In some implementations, the semiconductor chip 200 and the first redistribution substrate 100 may be electrically connected through bonding wires. For example, the semiconductor chip 200 may be provided in a face-up state on the first redistribution substrate 100. The semiconductor chip 200 may include chip upper pads provided on the top surface of the semiconductor chip 200. The bonding wires may extend from top surfaces of the chip upper pads to be coupled to the first upper pads of the first redistribution substrate 100. The chip upper pads may be electrically connected through the bonding wires to the first upper pads of the first redistribution substrate 100. The bonding wires may include metal, such as gold (Au).

FIG. 1 depicts that one semiconductor chip is mounted on a top surface of the first redistribution substrate 100, but the present disclosure is not limited thereto. In some implementations, a plurality of semiconductor chips and/or passive elements may be mounted on the top surface of the first redistribution substrate 100. The plurality of semiconductor chips or passive elements may be disposed spaced apart from each other (e.g., horizontally) on the top surface of the first redistribution substrate 100. The passive elements may include a capacitor, an inductor, a resistor, or an integrated passive device (IPD).

An underfill layer 130 may be provided between the top surface of the first redistribution substrate 100 and the bottom surface of the semiconductor chip 200. The underfill layer 130 may fill a space between the first redistribution substrate 100 and the semiconductor chip 200 and surround the chip connection terminals 230. FIG. 1 depicts that the underfill layer 130 entirely covers the top surface of the first redistribution substrate 100, but the present disclosure is not limited thereto. In some implementations, the underfill layer 130 may be provided only in a space between the first redistribution substrate 100 and the semiconductor chip 200. The underfill layer 130 may not be provided on a region of the first redistribution substrate 100 where the semiconductor chip 200 is not provided, and the top surface of the first redistribution substrate 100 may be exposed.

A molding layer 300 may be provided on the first redistribution substrate 100. The molding layer 300 may cover a top surface of the underfill layer 130. The molding layer 300 may surround the semiconductor chip 200. The molding layer 300 may cover the semiconductor chip 200. In some implementations, the top surface of the semiconductor chip 200 may be exposed on or through a top surface of the molding layer 300. The molding layer 300 may include a dielectric material. For example, the molding layer 300 may include an epoxy molding compound (EMC).

A second redistribution substrate 400 may be provided on the top surface of the molding layer 300. The second redistribution substrate 400 may cover the top surface of the molding layer 300. The second redistribution substrate 400 may include one or more second substrate wiring layers that are sequentially stacked on the top surface of the molding layer 300. Each of the second substrate wiring layers may include a second dielectric pattern 410 and a second conductive pattern 420. The second conductive pattern 420 of one second substrate wiring layer may be electrically connected to the second conductive pattern 420 of a neighboring other second substrate wiring layer. The following will describe the second dielectric pattern 410 and the second conductive pattern 420 of the one second substrate wiring layer.

The second dielectric pattern 410 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers.

The second conductive pattern 420 may be provided on a top surface of the second dielectric pattern 410. The second conductive pattern 420 may protrude onto the top surface of the second dielectric pattern 410. The second conductive pattern 420 may horizontally extend on the top surface of the second dielectric pattern 410. The second conductive pattern 420 positioned on the top surface of the second dielectric pattern 410 may be covered with an overlying other second dielectric pattern 410. The second conductive pattern 420 may be a pad or wiring part of the second substrate wiring layer. For example, the second conductive pattern 420 may be a component for horizontal redistribution in the second redistribution substrate 400. The second conductive pattern 420 may include a conductive material. For example, the second conductive pattern 420 may include copper (Cu).

The second conductive pattern 420 may have a damascene structure, e.g., formed in a damascene process. For example, the second conductive pattern 420 may have a via that protrudes onto a bottom surface of the second conductive pattern 420. The via may be a component for connection between the second conductive patterns 420 of the second wiring layers that are vertically adjacent to each other. For example, the via may extend from the bottom surface of the second conductive pattern 420, and may penetrate the second dielectric pattern 410 to be coupled to a top surface of the second conductive pattern 420 of an underlying another second substrate wiring layer. In this configuration, an upper portion of the second conductive pattern 420 positioned on the second dielectric pattern 410 may be a head part used as a horizontal line or pad, and the via of the second conductive pattern 420 may be a tail part. The second conductive pattern 420 may have a T shape.

Referring together to FIGS. 1 and 2, second upper pads 430 may be provided on a top surface of the second redistribution substrate 400. The second upper pads 430 may correspond to the head part of the second conductive pattern 420 in an uppermost one of the second substrate wiring layers. The second upper pads 430 may be a portion of the second conductive pattern 420 that protrudes from the second dielectric pattern 410 of the second redistribution substrate 400, or may be separate pads that are disposed on the second dielectric pattern 410 of the second redistribution substrate 400 to come into connection with the second conductive pattern 420. The second upper patterns 430 may include a conductive material. For example, the second upper pads 430 may include copper (Cu). The second upper pads 430 may have uneven top and lateral surfaces. A first height H1 from the top surface of the second dielectric pattern 410 to the top surfaces of the second upper pads 430 may range from about 5 μm to about 8 μm. The following will describe in detail a shape of an example of a second upper pad 430.

A first recess RS1 may be provided on the top surface of the second upper pad 430. The first recess RS1 may be directed from the top surface of the second upper pad 430 into an interior of the second upper pad 430. The first recess RSI may be positioned on a central portion of the second upper pad 430. A peripheral portion of the second upper pad 430 may protrude upwards from a bottom surface of the first recess RS1. The first recess RS1 may have a width about 0.8 times to about 0.95 times that of the second upper pad 430. The second upper pad 430 and the first recess RSI may each have a circular planar shape or a polygonal planar shape. The planar shape of the second upper pad 430 may be the same as that of the first recess RS1. The shape and size of the first recess RS1 and the second upper pad 430, however, are not limited thereto.

The second upper pad 430 may further include a first seed layer interposed between a bottom surface of the second upper pad 430 and the second dielectric pattern 410 positioned on the bottom surface of the second upper pad 430. The first seed layer may have a width the same as that of the second upper pad 430. A material of the first seed layer may be the same as that of the second upper pad 430. The first seed layer may have a planar shape the same as that of a bottom surface of the second upper pad 430. The first seed layer and the second upper pad 430 may be provided as a single unitary piece. The first seed layer and the second upper pad 430 may have a continuous configuration, and an invisible interface may be present between the first seed layer and the second upper pad 430. The first recess RS1 may completely penetrate the second upper pad 430. A top surface of the first seed layer may be partially exposed by the first recess RS1. A second height H2 from the bottom surface of the first recess RS1 to the top surface of the second upper pad 430 may range from about 5 μm to about 8 μm. A third height H3 from a bottom surface of the first seed layer, or a top surface of the second dielectric pattern 410 positioned on the bottom surface of the second upper pad 430, to the bottom surface of the first recess RS1 may range from about 1 μm to about 3 μm. For example, the first seed layer may have a height of about 1 μm to about 3 μm. In some implementations, the first seed layer may not be provided.

A metal layer 440 may be disposed on the bottom surface of the first recess RS1. A bottom surface of the metal layer 440 may be positioned on a central portion of the bottom surface of the first recess RS1.

The metal layer 440 may be formed of two or more layers. For example, the metal layer 440 may include a first metal layer 442 and a second metal layer 444 disposed on a top surface of the first metal layer 442. The first metal layer 442 may include a lower metal layer 446 and an upper metal layer 448 that protrudes upward from a central portion of a top surface of the lower metal layer 446. The lower metal layer 446 may be positioned on the central portion of the bottom surface of the first recess RS1. The lower metal layer 446 may have a width less than that of the first recess RS1. The lower metal layer 446 may have a lateral surface spaced apart from an inner lateral surface of the first recess RS1. The lateral surface of the lower metal layer 446 may face the inner lateral surface of the first recess RS1. For example, the lower metal layer 446 may cover the central portion of the bottom surface of the first recess RSI and expose a peripheral portion of the bottom surface of the first recess RS1. A spacing distance between the lateral surface of the lower metal layer 446 and the inner lateral surface of the first recess RS1 may range from about 15 um to about 25 μm. In some implementations, the width of the lower metal layer 446 may be about 0.8 times to about 0.9 times that of the first recess RS1.

The upper metal layer 448 may protrude from the top surface of the lower metal layer 446. The bottom surface of the upper metal layer 448 may have a planar shape and an area the same as those of the top surface of the lower metal layer 446. The upper metal layer 448 may have a width the same as that of the lower metal layer 446. For example, the width of the upper metal layer 448 may be less than that of the first recess RS1. The upper metal layer 448 may have a lateral surface spaced apart from the inner lateral surface of the first recess RS1. The lateral surface of the upper metal layer 448 may face the inner lateral surface of the first recess RS1. When viewed in a plan view (e.g., a top view), the upper metal layer 448 may completely overlap the lower metal layer 446. The lateral surface of the upper metal layer 448 may be coplanar with that of the lower metal layer 446.

The upper metal layer 448 and the lower metal layer 446 may be provided as a single unitary piece. The upper metal layer 448 and the lower metal layer 446 may have a continuous configuration, and an invisible interface may be present between the lower metal layer 446 and the bottom surface of the upper metal layer 448. A sum of heights of the lower and upper metal layers 446 and 448 may range from about 4 μm to about 8 μm. For example, the first metal layer 442 may be one metal layer in which the upper metal layer 448 and its corresponding lower metal layer 446 are provided as a single unitary piece, and the one metal layer may have a height of about 4 μm to about 8 μm. The top surface of the first metal layer 442 may be located at a lower level than that of the top surface of the second upper pad 430.

The second metal layer 444 may surround the first metal layer 442. The second metal layer 444 may completely cover the top and lateral surfaces of the first metal layer 442. For example, the second metal layer 444 may extend from the top surface of the first metal layer 442 along the lateral surface of the first metal layer 442, thereby contacting the bottom surface of the first recess RS1. In the first recess RS1, the second metal layer 444 may cause the first metal layer 442 not to be exposed. The second metal layer 444 may have a thickness less than that of the first metal layer 442.

The metal layers 440 may include a material for increasing bondability between the second upper pads 430 and connection terminals 450 which will be discussed below. The metal layers 440 may include a conductive material. For example, the conductive material may include metal such as nickel (Ni), gold (Au), and silver (Ag). The second metal layers 444 may include a material that suppresses oxidation of the first metal layers 442. The second metal layers 444 may include a material different from that of the first metal layers 442. For example, the first metal layers 442 may include nickel (Ni), and the second metal layers 444 may include gold (Au), silver (Ag), or an alloy thereof.

FIG. 1 depicts that the metal layer 440 is formed of two layers, the first metal layer 442 and the second metal layer 444, but the present disclosure is not limited thereto. In some implementations, the metal layer 440 may be formed of one layer. In this case, the metal layer 440 may be substantially the same as or similar to the first metal layer 442 and the second metal layer 444 being provided as a single unitary piece. The first metal layer 442 and the second metal layer 444 may have a continuous configuration, and an invisible interface may be present between the first metal layer 442 and the second metal layer 444.

The first recesses RS1 may limit regions where the metal layers 440 are provided on the second upper pads 430. For example, the first recesses RS1 may define regions where the metal layers 440 are provided. As the metal layers 440 are disposed on the bottom surfaces of the first recesses RS1, the metal layers 440 may not extend along any of the top and lateral surfaces of the second upper pads 430, e.g., may be spaced apart from inner lateral surfaces of first recesses RS1. An adhesion force between the metal layers 440 and a third substrate protection layer 460 which will be discussed below may be less than an adhesion force between the second upper pads 430 and the third substrate protection layer 460. The first recesses RSI may prevent the metal layers 440 from extending between the second upper pads 430 and the third substrate protection layer 460, and an increased adhesion force may be provided between the second upper pads 430 and the third substrate protection layer 460. As a result, in some implementations, a semiconductor package may have increased structural stability.

A third substrate protection layer 460 may be provided on the top surface of the second redistribution substrate 400. The third substrate protection layer 460 may cover the uppermost second substrate wiring layer. The third substrate protection layer 460 may cover an uppermost second dielectric pattern 410 and surround the second upper pads 430. At least a portion of the second upper pads 430 may be exposed on or through a top surface of the third substrate protection layer 460. For example, the third substrate protection layer 460 may cover the peripheral portions of the second upper pads 430, and the central portions of the second upper pads 430 may be outwardly exposed with respect to the third substrate protection layer 460. On the top surfaces of the second upper pads 430, the third substrate protection layer 460 may extend along the inner lateral surfaces of the first recesses RS1. The third substrate protection layer 460 may entirely cover portions of the top surfaces of the first seed layers exposed by the first recesses RS1. The third substrate protection layer 460 may fill spaces between lateral surfaces of the metal layers 440 and the inner lateral surfaces of the first recesses RS1. The third substrate protection layer 460 may cover portions of top surfaces of the metal layers 440. At least portions of the top surfaces of the metal layers 440 may be outwardly exposed with respect to the third substrate protection layer 460. For example, the top surfaces of the metal layers 440 may have central portions that are outwardly exposed with respect to the third substrate protection layer 460, and may also have peripheral portions that are covered with the third substrate protection layer 460. The third substrate protection layer 460 may include a dielectric material, such as solder resist. For example, the dielectric material may include one of epoxy resin, polyimide resin, bismaleimide triazine (BT) resin, and Teflon™ resin. The third substrate protection layer 460 may include a dielectric polymer or photo-imageable dielectric. As the third substrate protection layer 460 extends along the inner lateral surfaces of the first recesses RS1, there may be increased contact regions between the third substrate protection layer 460 and the second upper pads 430. As wide areas are present between the third substrate protection layer 460 and the second upper pads 430, the third substrate protection layer 460 may be stably fixed on the top surface of the second redistribution substrate 400, and thus, in some implementations, a semiconductor package may improve in structural stability.

Connection terminals 450 may be provided which are coupled to the top surfaces of the metal layers 440. A bottom surface of the connection terminal 450 may be in contact with the top surface of the metal layer. The connection terminals 450 may be disposed on the central portions of the top surfaces of the metal layers 440. The connection terminals 450 may include solder balls or solder bumps. A semiconductor package may be mounted through the connection terminals 450 on an external apparatus. When an external apparatus is mounted on the top surface of the second redistribution substrate 400, top surfaces of the connection terminals 450 may be in contact with the external apparatus. The third substrate protection layer 460 may extend onto the top surfaces of the metal layers 440 to surround at least portions of lateral surfaces of the connection terminals 450. The lateral surfaces of the connection terminals 450 may have lower portions that are surrounded by the third substrate protection layer 460. The lateral surfaces of the connection terminals 450 may have upper portions that are exposed on the third substrate protection layer 460. As the third substrate protection layer 460 surrounds the lower portions of the lateral surfaces of the connection terminals 450, the connection terminals 450 may not extend along (e.g., be in contact with) any of the top and lateral surfaces of the second upper pads 430. For example, the connection terminals 450 can be spaced apart from the second upper pads 430. Accordingly, in some implementations, the connection terminals 450 may be stably coupled to the second upper pads 430, and a semiconductor package may improve in structural stability.

A semiconductor package may include a connection member through which the first redistribution substrate 100 and the second redistribution substrate 400 are connected on one side of the semiconductor chip 200. The connection member may be a metal post 310, as shown in FIG. 1. The metal post 310 may be disposed between the first redistribution substrate 100 and the second redistribution substrate 400. The metal post 310 may be disposed horizontally spaced apart from the semiconductor chip 200. The metal post 310 may vertically penetrate the molding layer 300. The metal post 310 may have one end connected to the first conductive pattern 120 of the first redistribution substrate 100. The one end of the metal post 310 may be in contact with the first upper pad of the first redistribution substrate 100. The metal post 310 may have another end connected to the second conductive pattern 420 of the second redistribution substrate 400. For example, the first redistribution substrate 100 and the second redistribution substrate 400 may be electrically connected through the metal post 310. The metal post 310 may have a shape tapered along one direction. In some implementations, the metal post 310 may have a relatively straight shape whose width is constant along a vertical direction. In some implementations, a seed/barrier layer may be provided between the metal post 310 and the molding layer 300. For example, the seed/barrier layer may cover a bottom or lateral surface of the metal post 310. The metal post 310 may be provided in plural, in some implementations. The metal post 310 may include a metallic material. The metallic material may include copper (Cu), aluminum (Al), silver (Ag), tin (Sn), gold (Au), nickel (Ni), lead (Pb), titanium (Ti), or any alloy thereof.

FIGS. 1 and 2 depict that the first recesses RS1 have flat inner lateral surfaces and constant height, but the first recesses RSI are not limited thereto.

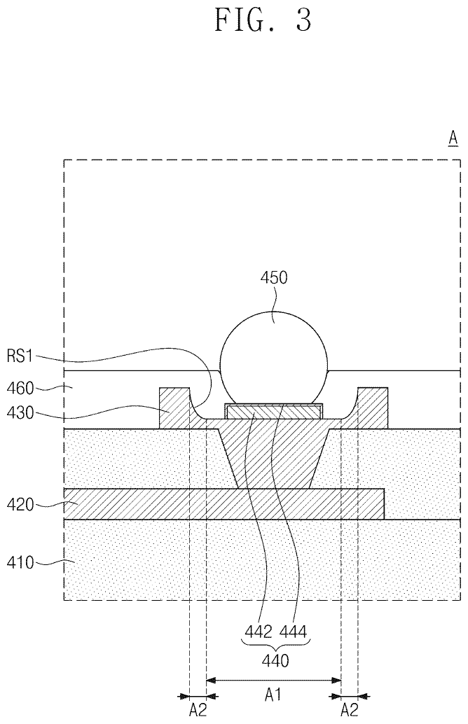

FIG. 3 illustrates a cross-sectional view showing the second upper pads 430 according to some implementations. For convenience of description, in FIG. 3, one of the second upper pads 430 of a semiconductor package will be enlarged, and some components may be omitted or merged into a single configuration. Except where noted otherwise or suggested otherwise by context, description of elements of FIGS. 1-2 can apply equally to the corresponding elements of FIG. 3.

Referring to FIG. 3, the first recesses RS1 may each have a height that is not constant along a direction perpendicular to a surface of the second redistribution substrate 400. Each of the first recesses RS1 may include a first region A1 and a second region A2 that surrounds the first region A1 when viewed in a plan view. The first region A1 may include a lowermost end of the first recess RS1. For example, the first region A1 may have a bottom surface that corresponds to the bottom surface of the first recess RS1. The second region A2 may have a lateral surface that corresponds to the flat inner lateral surface of the first recess RS1. The first region A1 may be a central portion of the first recess RS1, and the second region A2 may be an edge portion of the first recess RS1. Each of the first recess RS1 may further be provided with an intermediate surface that connects the inner lateral surface of the first recess RSI to the bottom surface of the first recess RS1. The intermediate surface may correspond to a bottom surface of the second region A2. For example, the bottom surface of the second region A2 may connect the lateral surface of the second region A2 to the bottom surface of the first region A1. The intermediate surface may be a round-shaped curved surface. For example, the intermediate surface may include a concave surface. An interval or distance between the intermediate surface and the bottom surface of the first seed layer or a top surface of the second dielectric pattern 410 positioned on the bottom surface of the second upper pad 430, may be measured in a direction perpendicular to the top surface of the second upper pad 430, and the interval or distance may increase with increasing horizontal distance from the bottom surface of the first region A1. In some implementations, the intermediate surface may be formed of a plurality of flat surfaces or a plurality of surfaces having obtuse angles.

FIG. 3 depicts that the second region A2 has a flat lateral surface and a round-shaped bottom surface, but the shape is not limited thereto. The second region A2 may have bottom and lateral surfaces each of which has a round shape. For example, the lateral surface of the second region A2 may be a region where the top surface of the second upper pad 430 meets the bottom surface of the second region A2. For example, the lateral surface of the second region A2 may connect the intermediate surface to the top surface of the second upper pad 430. The lateral surface of the second region A2 may be a curved surface that is rounded to have a certain radius of curvature. An interval between an outer lateral surface of the second upper pad 430 and the lateral surface of the second region A2 may be measured in a direction parallel to the top surface of the second upper pad 430, and the interval may decrease with increasing distance from the top surface of the second upper pad 430. For example, the first recess RS1 may have a width that increases with increasing distance from the top surface of the second redistribution substrate 400 and then decreases with decreasing distance from the top surface of the second upper pad 430.

FIG. 1 depicts that the metal layers 440 are spaced apart from the inner lateral surfaces of the first recesses RS1, but the present arrangement is not limited thereto.

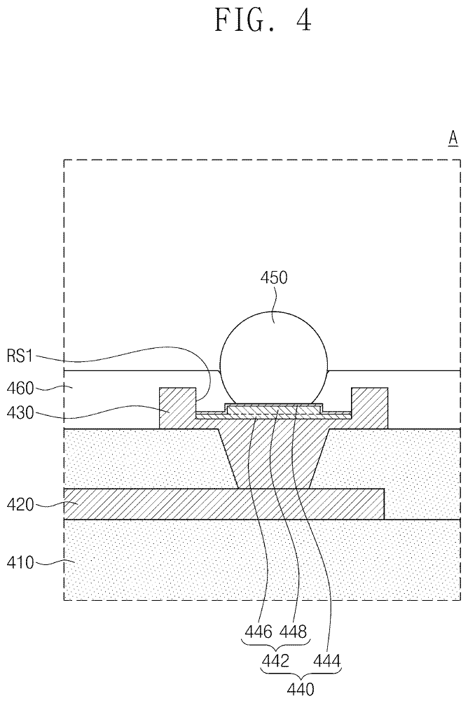

FIG. 4 illustrates a cross-sectional view showing the second upper pads 430 according to some implementations. For convenience of description, in FIG. 4, one of the second upper pads 430 of a semiconductor package will be enlarged, and some components will be omitted or merged into a single configuration. For convenience of description, the following will describe a pair of corresponding first metal and second metal layers 442 and 444 that constitute one metal layer 440. Except where noted otherwise or suggested otherwise by context, description of elements of FIGS. 1-2 can apply equally to the corresponding elements of FIG. 4.

Referring to FIG. 4, the metal layer 440 may entirely cover the bottom surface of the first recess RSI and contact the inner lateral surface of the first recess RS1. For example, the lower metal layer 446 may extend from a central portion of the bottom surface of the first recess RS1 toward the inner lateral surface of the first recess RS1. The lower metal layer 446 may entirely cover the bottom surface of the first recess RS1. The lower metal layer 446 may entirely cover a portion of the top surface of the first seed layer exposed by the first recess RS1. Thus, the top surface of the first seed layer may not be outwardly exposed. The lateral and bottom surfaces of the lower metal layer 446 may be in contact with the inner lateral surface of the first recess RS1.

The upper metal layer 448 may protrude from the top surface of a corresponding lower metal layer 446. The upper metal layer 448 may have a bottom surface positioned on a central portion of the top surface of the lower metal layer 446. The central portion of the top surface of the lower metal layer 446 may be in contact with the bottom surface of the upper metal layer 448, and a peripheral portion of the top surface of the lower metal layer 446 may be outwardly exposed with respect to the upper metal layer 448. In this case, the upper metal layer 448 may be spaced apart from the lateral surface of the lower metal layer 446. The lower metal layer 446 may protrude onto a lateral surface of the upper metal layer 448. The lateral surface of the upper metal layer 448 may be spaced apart from the inner lateral surface of the first recess RS1. The lateral surface of the upper metal layer 448 may face the inner lateral surface of the first recess RS1. The upper metal layer 448 may have a cross-section having a rectangular shape or a square shape as shown in FIG. 4. The upper metal layer 448 may have a width about 0.8 times to about 0.9 times that of the first recess RS1. When viewed in a plan view, an entirety of the upper metal layer 448 may vertically overlap the lower metal layer 446. The upper metal layer 448 may have a thickness greater than that of the lower metal layer 446. The thickness of the upper metal layer 448 may be in the range of about 4 μmm to about 10 μm. FIG. 4 depicts that a top surface of the upper metal layer 448 is located at a level lower than that of the top surface of the second upper pad 430, but the arrangement is not limited thereto, and the top surface of the upper metal layer 448 may be located at a level the same as or higher than that of the top surface of the second upper pad 430. For example, an upper portion of the lateral surface of the upper metal layer 448 may be exposed on the second upper pad 430.

The upper metal layer 448 and the lower metal layer 446 may be provided as a single unitary piece. The upper metal layer 448 and the lower metal layer 446 may have a continuous configuration, and an invisible interface may be present between the lower metal layer 446 and the bottom surface of the upper metal layer 448. In such a configuration, a pair of corresponding upper and lower metal layers 448 and 446 may be connected to constitute one metal layer or the first metal layer 442. The first metal layer 442 may have a cross-section having a stepped shape. For example, the top surface of the first metal layer 442 may have an upper portion located at a level higher than that of a peripheral portion of the top surface of the first metal layer 442. In this case, the level of the central portion at the top surface of the first metal layer 442 may refer to a level of the top surface of the upper metal layer 448, and the level of the peripheral portion at the top surface of the first metal layer 442 may refer to a level of the top surface of the lower metal layer 446.

The second metal layer 444 may cover the top and lateral surfaces of the first metal layer 442. The second metal layer 444 may cover an entirety of the first metal layer 442 except the bottom surface of the lower metal layer 446 and the lateral surface of the lower metal layer 446 where the first metal layer 442 is in contact with the inner lateral surface of the first recess RS1. For example, the second metal layer 444 may cover the top and lateral surfaces of the upper metal layer 448 and also cover the peripheral portion of the top surface of the lower metal layer 446. As the second metal layer 444 covers the first metal layer 442 having the stepped cross-section, the second metal layer 444 may also have a cross-section having a stepped shape. A peripheral portion of a top surface of the second metal layer 444 may be lower than a central portion of the top surface of the second metal layer 444.

On the top surface of the second upper pad 430, the third substrate protection layer 460 may extend along the inner lateral surface of the first recess RS1. The third substrate protection layer 460 may fill a space between the lateral surface of the metal layer 440 and the inner lateral surface of the first recess RS1. The third substrate protection layer 460 may be in contact with the peripheral portion of the top surface of the second metal layer 444. The third substrate protection layer 460 may extend onto the top surface of the metal layer 440 to surround at least a portion of the lateral surface of the connection terminal 450. A lower portion of the lateral surface of the connection terminal 450 may be surrounded by the third substrate protection layer 460.

The first recess RS1 may limit a region where the metal layer 440 is provided on the second upper pad 430. The first recess RSI may define a region where the lower metal layer 446 is provided. As the lower metal layer 446 is disposed on the bottom surface of the first recess RS1, the lower metal layer 446 may not extend along any of the top and lateral surfaces of the second upper pad 430.

FIG. 4 depicts that the metal layer 440 is formed of two layers, the first metal layer 442 and the second metal layer 444, but the present disclosure is not limited thereto. In some implementations, the metal layer 440 may be formed of one layer. In this case, the metal layer 440 may be substantially the same as or similar to the first metal layer 442 and the second metal layer 444 being provided as a single unitary piece. The first metal layer 442 and the second metal layer 444 may have a continuous configuration, and an interface between the first metal layer 442 and the second metal layer 444 may be invisible. The third substrate protection layer 460 the protection layer may extend along the inner lateral surface of the first recess RS1 to contact a peripheral portion of the single unitary piece.

FIG. 1 depicts that the top surfaces of the metal layers 440 are located at a level lower than that of the top surfaces of the second upper pads 430, but the configuration is not limited thereto.

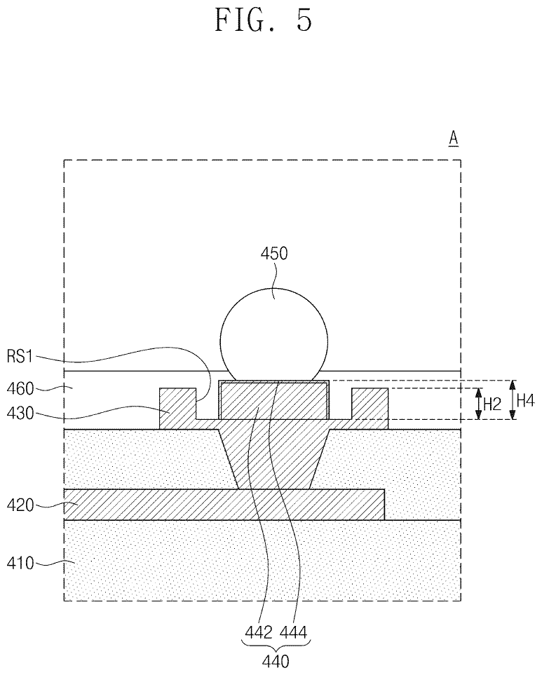

FIG. 5 illustrates a cross-sectional view showing the second upper pads 430 according to some implementations. For convenience of description, in FIG. 5, one of the second upper pads 430 of a semiconductor package will be enlarged, and some components will be omitted or merged into a single configuration. Except where noted otherwise or suggested otherwise by context, description of elements of FIGS. 1-2 can apply equally to the corresponding elements of FIG. 5.

Referring to FIG. 5, a metal layer 440 may be provided on a central portion of the bottom surface of the first recess RS1. A configuration of the metal layer 440 may be the same as that of the metal layer (see 440 of FIG. 1) discussed with reference to FIG. 1. For example, the metal layer 440 may include a first metal layer 442 and a second metal layer 444 that covers top and lateral surfaces of the first metal layer 442.

In some implementations, the metal layer 440 may have a top surface located at a level higher than that of the top surface of the second upper pad 430. The metal layer 440 may have a lateral surface whose upper portion is exposed on the second upper pad 430. A fourth height H4 or a distance from a bottom surface of the metal layer 440 to the top surface of the metal layer 440 may be greater than a second height H2 or a distance from the bottom surface of the first recess RSI to the top surface of the second upper pad 430. For example, a thickness of the first metal layer 442 may be the same as or greater than a height from the bottom surface of the first recess RS1 to the top surface of the second upper pad 430. The second metal layer 444 may surround the first metal layer 442. The second metal layer 444 may entirely cover the top and lateral surfaces of the first metal layer 442. The second metal layer 444 may have a thickness less than that of the first metal layer 442.

On the top surface of the second upper pad 430, the third substrate protection layer 460 may extend along the inner lateral surface of the first recess RS1. The third substrate protection layer 460 may fill a space between the lateral surface of the metal layer 440 and the inner lateral surface of the first recess RS1. The third substrate protection layer 460 may cover an exposed peripheral portion of the bottom surface of the first recess RS1. The third substrate protection layer 460 may cover a portion of the top surface of the metal layer 440. For example, the top surface of the metal layer 440 may have a central portion that is outwardly exposed with respect to the third substrate protection layer 460, and may also have a peripheral portion that is covered with the third substrate protection layer 460. The third substrate protection layer 460 may extend onto the top surface of the metal layer 440 to surround at least a portion of the lateral surface of the connection terminal 450. A lower portion of the lateral surface of the connection terminal 450 may be surrounded by the third substrate protection layer 460.

FIG. 1 depicts that the via of the first conductive pattern 120 protrudes from the lower surface of the first conductive pattern 120 and the semiconductor chip 200 is mounted on the first redistribution substrate 100 by flip chip bonding, but the configuration is not limited thereto.

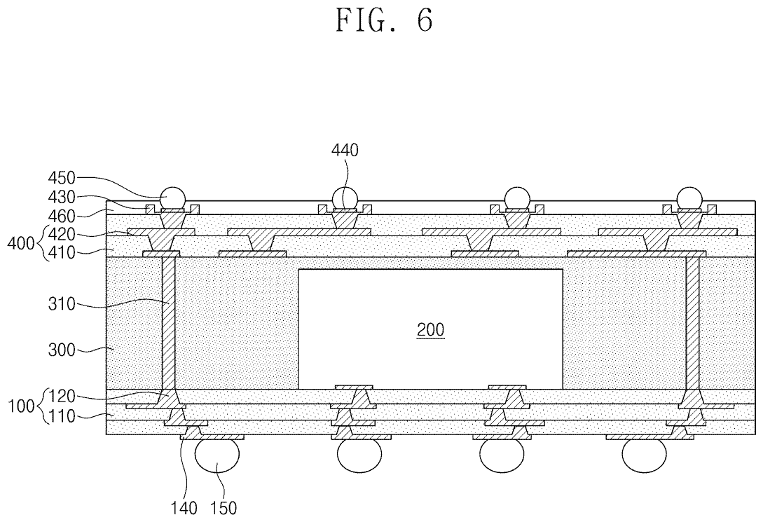

FIG. 6 illustrates a cross-sectional view showing a semiconductor package according to some implementations. For convenience of description, some components will be omitted or merged into a single configuration in FIG. 6. Except where noted otherwise or suggested otherwise by context, description of elements of FIGS. 1-2 can apply equally to the corresponding elements of FIG. 6.

Referring to FIG. 6, the semiconductor chip 200 may be directly mounted on the first redistribution substrate 100. The first conductive pattern 120 of the first redistribution substrate 100 may have an inverse T shape. For example, the first conductive pattern 120 may be provided on a bottom surface of the first dielectric pattern 110. The first conductive pattern 120 may protrude onto the bottom surface of the first dielectric pattern 110. The first conductive pattern 120 may horizontally extend on the bottom surface of the first dielectric pattern 110. On the bottom surface of the first dielectric pattern 110, the first conductive pattern 120 may be covered with an underlying other first dielectric pattern 110. The first conductive pattern 120 may have a damascene structure, e.g., formed in a damascene process. The first conductive pattern 120 may have a via that protrudes onto a top surface of the first conductive pattern 120. The via may be a component for vertical connection between neighboring first conductive patterns 120. For example, the via may extend from the top surface of the first conductive pattern 120, and may penetrate the first dielectric pattern 110 to be coupled to a bottom surface of an overlying other first conductive pattern 120. A lower portion of the first conductive pattern 120 positioned on the bottom surface of the first dielectric pattern 110 may be a head part used as a horizontal line or pad, and the via of the first conductive pattern 120 may be a tail part.

The semiconductor chip 200 may be disposed on the first redistribution substrate 100. A bottom surface of the semiconductor chip 200 may be in contact with a top surface of the first redistribution substrate 100. Chip lower pads may be electrically connected to the first conductive pattern 120 of the first redistribution substrate 100. For example, on a contact surface between the semiconductor chip 200 and the first redistribution substrate 100, the chip lower pads may be in direct contact with the first conductive pattern 120 of the first redistribution substrate 100. As the semiconductor chip 200 is directly connected to the first redistribution substrate 100, no connection terminals (e.g., chip connection terminals 230 of FIG. 1) may be disposed on the bottom surface of the semiconductor chip 200.

FIG. 6 depicts that a top surface of an uppermost first conductive pattern 120 is coplanar with a top surface of an uppermost first dielectric pattern 110, and that the metal post 310 is directly connected to the semiconductor chip 200, but arrangements are not limited thereto. The first redistribution substrate 100 may be provided on its top surface with first upper pads connected to the uppermost first conductive pattern 120. The first upper pads may be substantially the same as or similar to the first upper pads discussed with reference to FIG. 1. For example, the first upper pads may be a portion of the first conductive pattern 120 that protrudes onto the top surface of the uppermost first dielectric pattern 110, or may be separate pads that are disposed on the top surface of the first dielectric pattern 110 to come into connection with the first conductive patterns 120. The first upper pads may be in contact with a bottom surface of the metal post 310 and the chip lower pads of the semiconductor chip 200 to electrically connect the metal post 310 and the semiconductor chip 200 to the first redistribution substrate 100.

FIG. 1 illustrates that the first upper pads have flat top surfaces, but the first upper pads are not limited thereto.

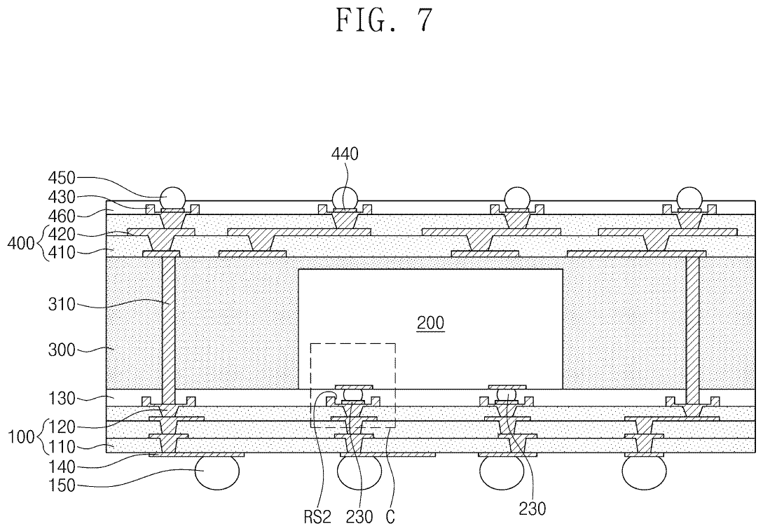

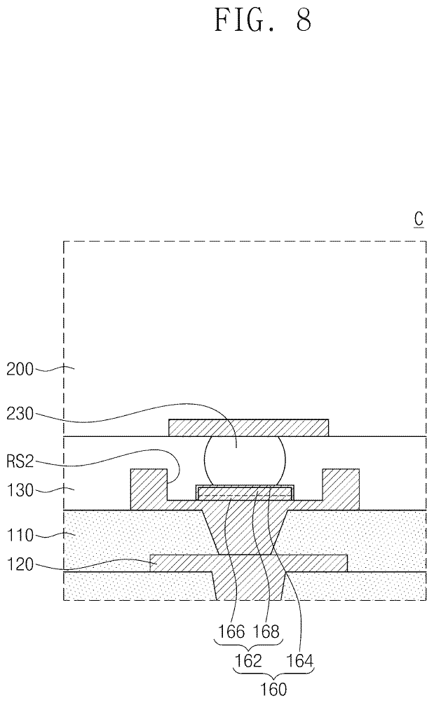

FIG. 7 illustrates a cross-sectional view showing a semiconductor package according to some implementations. For convenience of description, some components will be omitted or merged into a single configuration in FIG. 7. FIG. 8 illustrates an enlarged view of section C depicted in FIG. 7, showing first upper pads according to some implementations. Except where noted otherwise or suggested otherwise by context, description of elements of FIGS. 1-2 can apply equally to the corresponding elements of FIGS. 7-8.

Referring to FIGS. 7 and 8, first upper pads, shown for example in section C, may have substantially similar structures as those of the second upper pads 430 discussed with reference to FIG. 1. For example, the first upper pads may include second recesses RS2 that are directed from top surfaces of the first upper pads toward insides of the first upper pads. The second recesses RS2 may be positioned on central portions of the first upper pads. The second recesses RS2 may have a width about 0.8 times to about 0.95 times that of the first upper pads.

The first upper pads may further include second seed layers interposed between bottom surfaces of the first upper pads and the first dielectric pattern 110 positioned on the bottom surfaces of the first upper pads. For example, a material of the second seed layers may be the same as that of the first upper pads. The second seed layer and the first upper pad may be provided as a single unitary piece. The second seed layer and the first upper pad may have a continuous configuration, and an invisible interface may be present between the second seed layer and the first upper pad. The second recesses RS2 may completely penetrate the first upper pads. Portions of top surfaces of the second seed layers may be exposed by the second recesses RS2. The second seed layers may not be provided, in some implementations.

Metal patterns 160 may be disposed on bottom surfaces of the second recesses RS2 of the first upper pads connected to chip lower pads of the semiconductor chip 200. The metal pattern 160 may be substantially similar to the metal layer 440 discussed with reference to FIG. 2. For example, the metal pattern 160 may be formed of two or more layers. The metal pattern 160 may include a third metal layer 162 and a fourth metal layer 164 disposed on a top surface of the third metal layer 162. The third metal layer 162 and the fourth metal layer 164 may be substantially similar to the first metal layer 442 and the second metal layer 444, respectively, discussed with reference to FIG. 2.

The third metal layer 162 may include a lower third metal layer 166 and an upper third metal layer 168 that protrudes onto a central portion of a top surface of the lower third metal layer 166. The lower third metal layer 166 may be disposed on the bottom surface of the second recess RS2. A bottom surface of the lower third metal layer 166 may be positioned on a central portion of the bottom surface of the second recess RS2. A lateral surface of the lower third metal layer 166 may be spaced apart from an inner lateral surface of the second recess RS2. The lower third metal layer 166 may have a width about 0.8 times to about 0.9 times that of the second recess RS2.

The upper third metal layer 168 may protrude from the top surface of the lower third metal layer 166. The upper third metal layer 168 may have a bottom surface whose planar shape and area are the same as those of the top surface of the lower third metal layer 166. The upper third metal layer 168 may have a width the same as that of the lower third metal layer 166. When viewed in a plan view, the upper third metal layer 168 may completely overlap the lower third metal layer 166. For example, the upper third metal layer 168 may have a lateral surface coplanar with that of the lower third metal layer 166. The lateral surface of the upper third metal layer 168 may be spaced apart from the inner lateral surface of the second recess RS2.

The upper third metal layer 168 and the lower third metal layer 166 may be provided as a single unitary piece. The upper third metal layer 168 and the lower third metal layer 166 may have a continuous configuration, and an invisible interface may be present between the lower third metal layer 166 and the bottom surface of the upper third metal layer 168. A sum of heights of the lower and upper third metal layers 166 and 168 may range from about 4 μm to about 8 μm. For example, the third metal layer 162 may include a single metal layer in which the upper and lower third metal layers 168 and 166 are provided as a single unitary piece, and the one metal layer may have a height of about 4 μm to about 8 μm.

The fourth metal layer 164 may surround the third metal layer 162. The fourth metal layer 164 may completely cover the top and lateral surfaces of the third metal layer 162. The fourth metal layer 164 may have a thickness less than that of the third metal layer 162. The fourth metal layer 164 may include a material that suppresses oxidation of the third metal layer 162. A material of the fourth metal layer 164 may be different from that of the third metal layer 162. For example, the third metal layer 162 may include nickel (Ni), and the fourth metal layer 164 may include gold (Au), silver (Ag), or an alloy thereof.

A chip connection terminal 230 may be provided which is coupled to a top surface of the metal pattern 160. A bottom surface of the chip connection terminal 230 may be in contact with the top surface of the metal pattern 160. The chip connection terminal 230 may be disposed on a central portion of the top surface of the metal pattern 160. The underfill layer 130 may extend onto the top surface of the metal pattern 160 to surround the chip connection terminal 230.

FIGS. 7 and 8 illustrate that the bottom surface of the upper third metal layer 168 has the same area and planar area as those of the top surface of the lower third metal layer 166, but the present disclosure is not limited thereto. The lower third metal layer 166 may extend from the central portion of the bottom surface of the second recess RS2 toward the inner lateral surface of the second recess RS2. The lower third metal layer 166 may entirely cover the bottom surface of the second recess RS2. The lateral and bottom surfaces of the lower third metal layer 166 may be in contact with the inner lateral surface of the second recess RS2. The bottom surface of the upper third metal layer 168 may be positioned on the central portion of the top surface of the lower third metal layer 166. The lateral surface of the upper third metal layer 168 may be spaced apart from the inner lateral surface of the second recess RS2. The upper third metal layer 168 may have a width about 0.8 times to about 0.9 times that of the second recess RS2. The upper third metal layer 168 may have a thickness greater than that of the lower third metal layer 166.

FIG. 7 depicts that the top surface of the metal pattern 160 is located at a level lower than that of a top surface of the first upper pad, but the configuration is not limited thereto, and the top surface of the metal pattern 160 may be located at a level higher than that of the top surface of the first upper pad.

FIG. 1 depicts that the metal post (see 310 of FIG. 1) corresponds to a connection member through which the first redistribution substrate 100 and the second redistribution substrate 400 are connected on one side of the semiconductor chip 200, but the connections are not limited thereto.

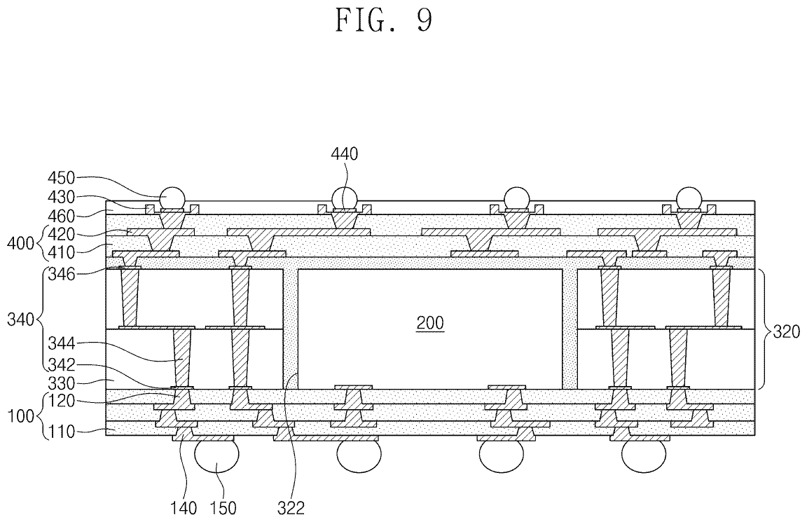

FIG. 9 illustrates a cross-sectional view showing a semiconductor package according to some implementations. For convenience of description, some components will be omitted or merged into a single configuration in FIG. 9. Referring to FIG. 9, metal posts (e.g., metal posts 310) may be replaced with a connection substrate 320 provided as a connection member. The connection substrate 320 may be disposed on the first redistribution substrate 100. The connection substrate 320 may have an opening 322 that penetrates therethrough. For example, the opening 322 may be shaped like an open hole that connects top and bottom surfaces of the connection substrate 320. The bottom surface of the connection substrate 320 may be in contact with a top surface of the first redistribution substrate 100. The connection substrate 320 may include a base layer 330 and a conductive member 340 that is a wiring pattern provided in the base layer 330. The conductive member 340 may be a wiring structure that vertically connects the first redistribution substrate 100 to the second redistribution substrate 400. For example, the base layer 330 may include silicon oxide. The conductive member 340 may be disposed closer than the opening 322 to an outside of the connection substrate 320. The conductive member 340 may include lower pads 342, vias 344, and upper pads 346. The lower pads 342 may be disposed on a lower portion of the connection substrate 320. FIG. 9 depicts that the first conductive pattern 120 of the first redistribution substrate 100 is directly coupled to the lower pads 342 of the connection substrate 320, but the arrangement is not limited thereto. The first redistribution substrate 100 may be provided on its top surface with pads connected to an uppermost first conductive pattern 120, and the connection substrate 320 may be mounted on the pads of the first redistribution substrate 100 through terminals such as solder balls or solder bumps provided on the lower pads 342 of the connection substrate 320.

The upper pads 346 may protrude from the top surface of the connection substrate 320. In some implementations, the upper pads 346 may be buried in the base layer 330, and top surfaces of the upper pads 346 may be coplanar with the top surface of the connection substrate 320. The upper pads 346 may be electrically connected to the second conductive patterns 420 of the second redistribution substrate 400. The vias 344 may penetrate the base layer 330 and electrically connect the lower pads 342 to the upper pads 346.

The lower pads 342 may be disposed on the bottom surface of the connection substrate 320. The lower pads 342 may be buried in the base layer 330, and bottom surfaces of the lower pads 342 may be coplanar with the bottom surface of the connection substrate 320. The vias 344 may penetrate the base layer 330 and electrically connect the upper pads 346 to the lower pads 342. The base layer 330 may include a polymer. For example, the base layer 330 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers. In some implementations, the base layer 330 may include a dielectric material. For example, the base layer 330 may include silicon oxide (SiO), silicon nitride (SiN), silicon oxynitride (SiON), or dielectric polymer. The upper pads 346, the lower pads 342, and the vias 344 may include a conductor or metal, such as copper (Cu).

The semiconductor chip 200 may be disposed on the first redistribution substrate 100. The semiconductor chip 200 may be disposed in the opening 322 of the connection substrate 320. The semiconductor chip 200 may be spaced apart from an inner wall of the opening 322. A bottom surface of the semiconductor chip 200 may be in contact with the top surface of the first redistribution substrate 100. Chip lower pads may be electrically connected to the first conductive patterns 120 of the first redistribution substrate 100.

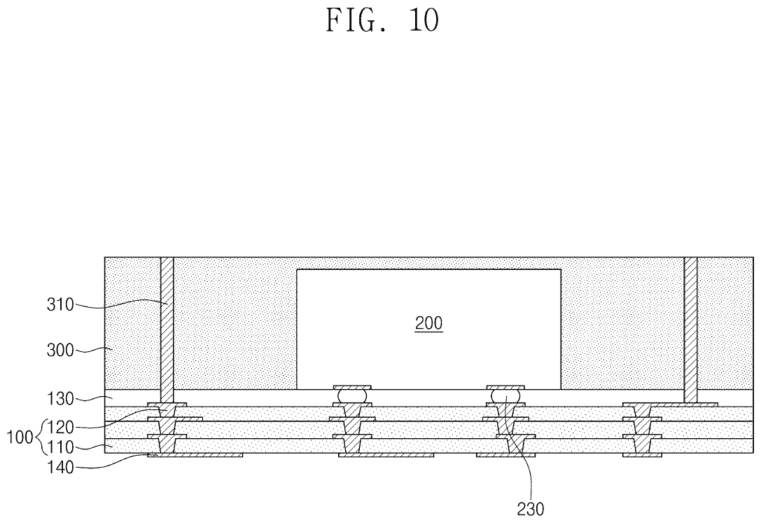

FIGS. 10 to 13 illustrate cross-sectional views showing a method of fabricating a semiconductor package according to some implementations. In FIGS. 10 to 13, some components of a semiconductor package will be omitted for convenience of description. The method of FIGS. 10 to 13, or portions thereof, can be applied, for example, to fabricate the semiconductor packages and elements thereof described with respect to FIGS. 1 to 9.

Referring to FIG. 10, a first redistribution substrate 100 may be formed. For example, a first dielectric pattern 110 and a first conductive pattern 120 may be formed to manufacture the first redistribution substrate 100. For example, a dielectric layer may be formed, and then the dielectric layer may be patterned to form the first dielectric pattern 110. A conductive layer may be formed on the dielectric layer, and then the conductive layer may be patterned to form the first conductive pattern 120. A portion of the first conductive pattern 120 may be exposed on the first dielectric pattern 110. In this way, one first substrate wiring layer may be formed, and the process mentioned above may be repeatedly performed to form the first redistribution substrate 100 having a plurality of first substrate wiring layers.

A semiconductor chip 200 may be provided on the first redistribution substrate 100. The semiconductor chip 200 may be substantially the same as the semiconductor chip 200 discussed with reference to FIG. 1. The semiconductor chip 200 may be disposed to allow its active surface to face the first redistribution substrate 100. The semiconductor chip 200 may be mounted on the first redistribution substrate 100 through chip connection terminals 230 disposed on a bottom surface of the semiconductor chip 200. An underfill layer 130 may be provided between a top surface of the first redistribution substrate 100 and the bottom surface of the semiconductor chip 200. The underfill layer 130 may fill a space between the first redistribution substrate 100 and the semiconductor chip 200. For example, a dielectric material may be coated between the first redistribution substrate 100 and the semiconductor chip 200, and then the dielectric material may be cured to form the underfill layer 130. The underfill layer 130 may surround the chip connection terminals 230.

A molding layer 300 may be formed on the first redistribution substrate 100. The molding layer 300 may cover the semiconductor chip 200. In some implementations, the molding layer 300 may be formed to expose a top surface of the semiconductor chip 200.

A metal post 310 may be formed in the molding layer 300. For example, a through hole may be formed which penetrates the molding layer 300 and exposes the first conductive pattern 120. The through hole may be filled with a conductive material to form the metal post 310.

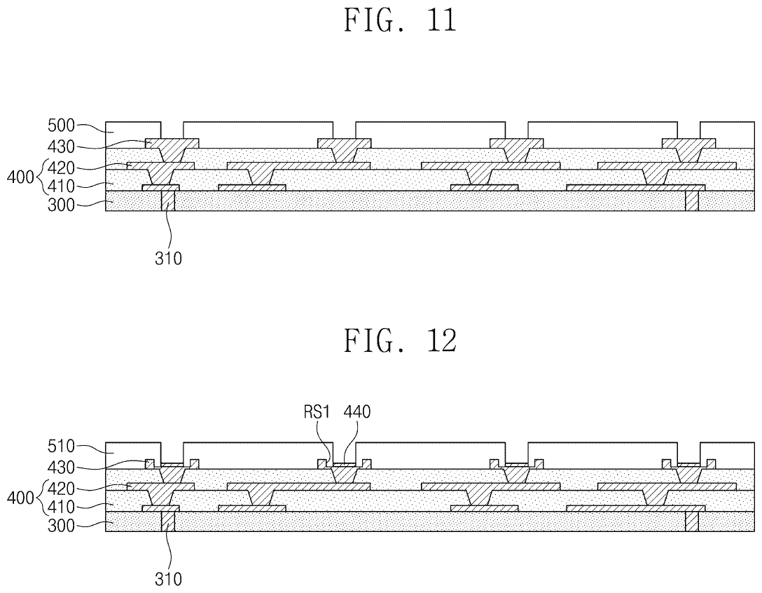

Referring to FIG. 11, a second redistribution substrate 400 may be formed on a resultant structure of FIG. 10. For example, a second dielectric pattern 410 and a second conductive pattern 420 may be formed on a top surface of the molding layer 300 to manufacture the second redistribution substrate 400. For example, a dielectric layer may be formed on the top surface of the molding layer 300, and then the dielectric layer may be patterned to form the second dielectric pattern 410. A conductive layer may be formed on the dielectric layer, and then the conductive layer may be patterned to form the second conductive pattern 420. A portion of the second conductive pattern 420 may be exposed on the second dielectric pattern 410. In this way, one second substrate wiring layer may be formed, and the process mentioned above may be repeatedly performed to form the second redistribution substrate 400 having a plurality of second substrate wiring layers. An uppermost end of the conductive layer may be patterned to form second upper pads 430.

A first mask pattern 500 (also referred to herein as a sacrificial layer) may be formed on the second upper pads 430. The first mask pattern 500 may have openings that expose central portions of top surfaces of the second upper pads 430. For example, an exposure process may allow the first mask pattern 500 to have first openings positioned on the second upper pads 430. The first openings may define the first recesses RS1 discussed with reference to FIG. 1. The first recesses RS1 may be formed through, for example, a wet etching process that uses an etchant. When the wet etching process is used to form the first recesses RS1, the first recesses RS1 may each have a width that decreases with increasing distance from the top surface of the second upper pad 430. The width of each of the first recess RS1, which width is measured on the top surface of the second upper pad 430, may be greater than that of each of the first openings. The first recesses RS1 may be etched to leave first seed layers of about 1 μm to about 3 μm from bottom surfaces of the second upper pads 430.

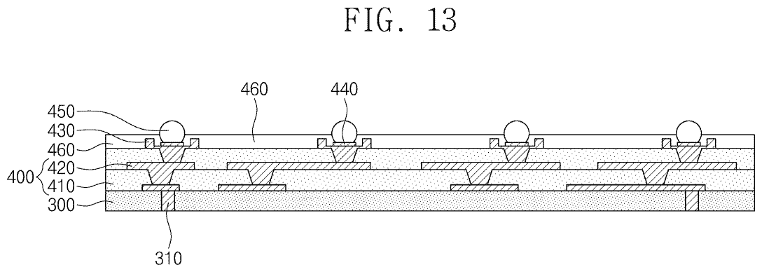

Referring to FIG. 12, the first mask pattern 500 may be removed. A second mask pattern 510 (also referred to herein as a sacrificial layer) may be formed on the second upper pads 430. The second mask pattern 510 may have openings that expose the top surfaces of the second upper pads 430. For example, the second mask pattern 510 may have openings that expose peripheral portions of bottom surface of the first recesses RS1. The second mask pattern 510 may undergo an exposure process to form second openings positioned on the central portions of the bottom surfaces of the first recesses RS1. The second openings may define regions where metal layers 440 are formed. A plating process may be performed on the regions exposed by the second openings. The plating process may cause the second openings of the second mask pattern 510 to be filled with a metallic material to form metal layers 440. The metal layers 440 may have a height of equal to or greater than about 4 μm. The metal layers 440 may include a metallic material, such as nickel (Ni), gold (Au), and silver (Ag), and may be formed on the bottom surfaces of the first recesses RS1. The second openings may have a width less than that of the first openings. For example, the first recesses RS1 may have a width greater than that of the metal layers 440, and the metal layers 440 may be formed spaced apart from inner lateral surfaces of the first recesses RS1. The metal layers 440 may each be formed of two or more layers. For example, first metal layers 442 may be formed on the bottom surfaces of the first recesses RS1, and then second metal layers 444 may be plated covering top and lateral surfaces of the first metal layers 442.

The plating process may be performed such that the metal layers 440 may extend from central portions of the first recesses RSI to a gap between the second mask pattern 510 and the second upper pads 430, thereby forming protrusions. A shape of the metal layer 440 having the protrusion may be the same as that of the metal layer 440 discussed with reference to FIG. 4.

Referring to FIG. 13, the second mask pattern 510 may be removed. Thus, the second upper pads 430 may be outwardly exposed. Afterwards, the second upper pads 430 may undergo a surface treatment process. The surface treatment process may cause the second upper pads 430 to have uneven top and lateral surfaces.

A third substrate protection layer 460 may be formed on the second upper pads 430. For example, a dielectric material may be deposited or coated to cover the second upper pads 430, thereby forming the third substrate protection layer 460. A laser process may be performed on the third substrate protection layer 460. The third substrate protection layer 460 may be irradiated with a laser such that a portion of the third substrate protection layer 460 may be removed to form third openings. The third openings may expose at least portions of top surfaces of the metal layers 440. For example, the third openings may expose central portions of the top surfaces of the metal layers 440. Connection terminals 450 may be formed on the exposed central portions of the top surfaces of the metal layers 440.

Referring back to FIG. 1, external terminals 150 may be formed on a bottom surface of the first redistribution substrate 100. The external terminals 150 may be provided on bottom surfaces of the external pads 140 exposed on the bottom surface of the first redistribution substrate 100. For example, the external terminals 150, such as solder balls or solder bumps, may be attached to the bottom surfaces of the external pads 140. As such, a semiconductor package may be fabricated as shown in FIG. 1.

In a semiconductor package according to some implementations, as a conductive pad has a recess and a dielectric layer fills the recess, an adhesion force between the dielectric layer and a substrate may be increased to provide the semiconductor package with improved structural stability.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although various examples have been described, it will be understood by one of ordinary skill in the art that variations in form and detail may be made therein without departing from the spirit and essential feature of the present disclosure. The above examples should thus be considered illustrative and not restrictive.

What is claimed is:

1. A wiring substrate, comprising:
a wiring pattern;
a dielectric pattern that covers the wiring pattern;
a substrate pad on the dielectric pattern, the substrate pad defining a recess that extends from a top surface of the substrate pad toward an interior of the substrate pad;
a metal layer on a bottom surface of the recess and spaced apart from an inner lateral surface of the recess; and
a protection layer on the dielectric pattern, the protection layer covering the substrate pad,
wherein the substrate pad extends through the dielectric pattern to contact the wiring pattern,
wherein at least a portion of the metal layer is exposed with respect to the protection layer, and
wherein the protection layer extends from the top surface of the substrate pad to fill a space between a lateral surface of the metal layer and the inner lateral surface of the recess.

2. The wiring substrate of claim 1, wherein a depth of the recess is in a range from 5 μm to 8 μm.

3. The wiring substrate of claim 1, wherein the metal layer includes:
a first metal layer on the bottom surface of the recess; and
a second metal layer that covers a top surface and a lateral surface of the first metal layer, wherein a thickness of the first metal layer is greater than a thickness of the second metal layer.

4. The wiring substrate of claim 1, wherein a top surface of the metal layer is at a level higher than a level of the top surface of the substrate pad.

5. The wiring substrate of claim 1, wherein a spacing between the lateral surface of the metal layer and the inner lateral surface of the recess is in a range of 15 μm to 25 μm.

6. The wiring substrate of claim 1, further comprising a connection terminal on a top surface of the metal layer and coupled to the metal layer, wherein the protection layer extends onto the top surface of the metal layer to surround at least a portion of a lateral surface of the connection terminal.

7. The wiring substrate of claim 1, wherein the top surface of the substrate pad is uneven, and wherein a lateral surface of the substrate pad is uneven.

8. The wiring substrate of claim 1, comprising a seed layer between the substrate pad and the dielectric pattern,
wherein the recess extends through the substrate pad and exposes the seed layer, and
wherein a height of the seed layer is in a range of 1 μm to 3 μm.

9. A semiconductor package, comprising:
a lower redistribution substrate;
a semiconductor chip on the lower redistribution substrate;
a molding layer on the lower redistribution substrate, the molding layer surrounding the semiconductor chip;
an upper redistribution substrate on the molding layer; and
a connection member through which the lower redistribution substrate and the upper redistribution substrate are electrically connected on a side of the semiconductor chip,
wherein the upper redistribution substrate includes:
a wiring pattern;
a dielectric pattern that covers the wiring pattern;
a substrate pad on the dielectric pattern, the substrate pad defining a recess on a central portion of the substrate pad, the recess extending from a top surface of the substrate pad toward an interior of the substrate pad;
a first metal layer on a bottom surface of the recess;
a protection layer that covers the dielectric pattern; and
a connection terminal on a top surface of the first metal layer,
wherein the first metal layer includes:
a lower metal layer; and
an upper metal layer that protrudes from a central portion of a top surface of the lower metal layer,
wherein a width of the lower metal layer is greater than a width of the upper metal layer, and
wherein the lower metal layer covers the bottom surface of the recess.

10. The semiconductor package of claim 9, wherein the protection layer extends along an inner lateral surface of the recess to contact a peripheral portion of the top surface of the lower metal layer.

11. The semiconductor package of claim 9, wherein
a thickness of the lower metal layer is less than a thickness of the upper metal layer, and the thickness of the upper metal layer is in a range of 4 μm to 10 μm.

12. The semiconductor package of claim 9, wherein the upper redistribution substrate further includes a second metal layer that covers the top surface of the first metal layer and a lateral surface of the first metal layer,
wherein the connection terminal is in contact with a top surface of the second metal layer,
wherein the first metal layer includes nickel (Ni), and wherein the second metal layer includes gold (Au) or silver (Ag).

13. The semiconductor package of claim 9, wherein a spacing between a lateral surface of the upper metal layer and an inner lateral surface of the recess is in a range of 15 μm to 25 μm.

14. The semiconductor package of claim 9, wherein a top surface of the upper metal layer is at a level higher than a level of the top surface of the substrate pad.

15. A method of fabricating a semiconductor package, the method comprising:
forming a wiring pattern and a dielectric pattern that covers the wiring pattern;
forming, on the dielectric pattern, a substrate pad that extends though the dielectric pattern to contact the wiring pattern;
forming a first sacrificial layer on the dielectric pattern;
patterning the first sacrificial layer to form a first opening that exposes a central portion of the substrate pad;
etching, using the first sacrificial layer as an etching mask, the substrate pad to form a recess in the substrate pad;
removing the first sacrificial layer;
forming a second sacrificial layer on the dielectric pattern;
patterning the second sacrificial layer to form a second opening that exposes a central portion of the recess, the second opening being spaced apart from an inner lateral surface of the recess;
forming a metal layer on the central portion of the recess, the central portion of the recess being exposed by the second opening;
removing the second sacrificial layer;
forming, on the dielectric pattern, a substrate protection layer that covers the substrate pad;
performing a laser process on the substrate protection layer to form a third opening that exposes a top surface of the metal layer; and
forming a connection terminal on the exposed top surface of the metal layer.

16. The method of claim 15, wherein the metal layer includes a protrusion that extends from the central portion of the recess.

17. The method of claim 15, wherein the substrate protection layer fills a space between a lateral surface of the metal layer and the inner lateral surface of the recess.

18. The method of claim 15, wherein a height of the recess is in a range of 5 μm to 8 μm.

19. The method of claim 15, wherein:
a width of the recess is greater than a width of the first opening, the width of the recess being measured at a top surface of the substrate pad, and
the width of the recess decreases with increasing distance from the top surface of the substrate pad.

20. The method of claim 15, wherein:
when viewed in a plan view, the substrate protection layer surrounds the connection terminal, and
at least a portion of the connection terminal protrudes onto a top surface of the substrate protection layer.
